(19) United States
(12) Patent Application Publication
(10) Pub. No.: US 2023/0081211 A1
(43) Pub. Date: Mar. 16, 2023

(54) SEMICONDUCTOR DEVICE AND PREPARATION METHOD THEREOF

(71) Applicant: Dynax Semiconductor, Inc., Suzhou (CN)

(72) Inventors: Yi PEI, Suzhou (CN); Jian LIU, Suzhou (CN); Xingxing WU, Suzhou (CN)

(73) Assignee: Dynax Semiconductor, Inc., Suzhou (CN)

(21) Appl. No.: 17/990,561

(22) Filed: Nov. 18, 2022

Related U.S. Application Data
(63) Continuation of application No. PCT/CN2020/096811, filed on Jun. 18, 2020.

(30) Foreign Application Priority Data
Jun. 18, 2019 (CN) 201910528572.X

(51) Int. Cl. H01L 29/40; H01L 29/20; H01L 29/06; H01L 29/778; H01L 29/66

(52) U.S. Cl. CPC H01L 29/402; H01L 29/2003; H01L 29/0692; H01L 29/7786; H01L 29/401; H01L 29/66462

(57) ABSTRACT

Disclosed are a semiconductor device and a preparation method thereof. The semiconductor device includes a substrate; a multilayer semiconductor layer located on a side of the substrate; and a source, a gate, a drain and a field plate structure located on a side, away from the substrate, of the multilayer semiconductor layer. The field plate structure includes a main body portion and a first extension portion; the main body portion is located between the gate and the drain; the first extension portion is connected to the main body portion and is located on a side, away from the multilayer semiconductor layer, of the gate; and the first extension portion at least partially overlaps the gate. By adopting the above technical solution, the probability of the breakdown, which occurs at the side of the gate near the drain, may be reduced, thereby increasing the reliability of semiconductor devices.

### CROSS-REFERENCE TO RELATED APPLICATIONS

The present application is a continuation application of International Application No. PCT/CN2020/096811, filed on Jun. 18, 2020, which claims priority to Chinese Patent Application No. 201910528572.X, filed on Jun. 18, 2019. Both applications are incorporated herein by reference in their entireties.

### TECHNICAL FIELD

The embodiments of the present application relate to the technical field of semiconductors, and in particular, to a semiconductor device and a preparation method thereof.

### BACKGROUND

The semiconductor material gallium nitride (GaN) has become a research hotspot due to its large band gap, high electron saturation drift velocity, high breakdown field strength, and good thermal conductivity.

Due to the strong two-dimensional electron gas in the AlGaN/GaN heterostructure, the High Electron Mobility Transistor (HEMT) formed by the AlGaN/GaN heterostructure is usually a depletion-mode semiconductor device. However, during an operation of the semiconductor device, a distribution of electric field lines in a depletion region of a barrier layer is not uniform, and an edge of a side of a gate near a drain tends to collect most of the electric field lines and the electric field strength is higher, and at the higher electric field strength, the leakage current of the semiconductor device will increase significantly, resulting in avalanche breakdown of the semiconductor device.

In order to improve the breakdown voltage of semiconductor devices, give full play to the advantages of higher output power, and increase the reliability of semiconductor devices, researchers used field plate structure to transform them. However, there is still a breakdown problem in a semiconductor device using a traditional field plate structure, the reliability of the semiconductor device is poor, and it is easy to fail, which greatly limits the application of the semiconductor device.

### SUMMARY

In view of this, the embodiments of the present application provide a semiconductor device and a preparation method thereof, which solve the problem of poor reliability of the existing semiconductor device.

In a first aspect, embodiments of the present application provide a semiconductor device, including: a substrate; a multilayer semiconductor layer located on a side of the substrate; a source, a gate and a drain located on a side, away from the substrate, of the multilayer semiconductor layer, wherein the gate is located between the source and the drain; and a field plate structure located on the side, away from the substrate, of the multilayer semiconductor layer. The field plate structure includes a main body portion and a first extension portion; the main body portion is located between the gate and the drain; the first extension portion is connected to the main body portion, and the first extension portion is located on a side, away from the multilayer semiconductor layer, of the gate; and a vertical projection of the first extension portion on a plane where the substrate is located at least partially overlaps a vertical projection of the gate on the plane where the substrate is located.

With reference to the first aspect, in some implementations of the first aspect, the first extension portion includes a first part, and a vertical projection of the first part on the plane where the substrate is located partially overlaps the vertical projection of the gate on the plane where the substrate is located.

With reference to the first aspect, in some implementations of the first aspect, along a direction from the gate to the drain, an extension length of the first part is L₁, and an extension length of the gate is L_{G}, wherein 0.1*L_{G}<L₁<0.65*L_{G}.

With reference to the first aspect, in some implementations of the first aspect, along a direction from the gate to the drain, an extension length of the first part is L₁, and an extension length of the main body portion is L₂, wherein L₁<L₂.

With reference to the first aspect, in some implementations of the first aspect, the first extension portion further includes a second part, and the second part extends toward a direction from the gate to the source to a place between the gate and the source and extends toward the multilayer semiconductor layer; and the vertical projection of the first part on the plane where the substrate is located and a vertical projection of the second part on the plane where the substrate is located are adjacent without overlapping.

With reference to the first aspect, in some implementations of the first aspect, along a direction from the gate to the drain, an extension length of the second part between the gate and the source is L₃, and a distance between the gate and the source is L_{GS}, wherein 0<L₃<0.5*L_{GS}.

With reference to the first aspect, in some implementations of the first aspect, along a direction from the gate to the drain, an extension length of the main body portion is L₂, and a distance between the gate and the drain is L_{GD}, wherein L₂<0.6*L_{GD}.

With reference to the first aspect, in some implementations of the first aspect, the multilayer semiconductor layer includes a nucleation layer, a buffer layer, a channel layer and a barrier layer arranged in sequence, and a two-dimensional electron gas is formed in the multilayer semiconductor layer.

With reference to the first aspect, in some implementations of the first aspect, along a direction perpendicular to the substrate, a distance L₄ between the first extension portion and the channel layer satisfies 300 nm<L₄<2000 nm.

With reference to the first aspect, in some implementations of the first aspect, the semiconductor device further includes at least one dielectric layer, and the dielectric layer covers an upper surface and a side surface of the gate.

With reference to the first aspect, in some implementations of the first aspect, in an extending direction of the gate, a width of the first extension portion and a width of the main body portion are the same.

In a second aspect, embodiments of the present application provide a preparation method of a semiconductor device, including: providing a substrate; preparing a multilayer semiconductor layer on a side of the substrate; preparing a source, a gate and a drain on a side, away from the substrate, of the multilayer semiconductor layer, wherein the gate is located between the source and the drain; and preparing a field plate structure on the side, away from the substrate, of the multilayer semiconductor layer. The field plate structure includes a main body portion and a first extension portion; the main body portion is located between the gate and the drain; the first extension portion is connected to the main body portion, and the first extension portion is located on a side, away from the multilayer semiconductor layer, of the gate; and a vertical projection of the first extension portion on a plane where the substrate is located at least partially overlaps a vertical projection of the gate on the plane where the substrate is located.

With reference to the second aspect, in some implementations of the second aspect, the first extension portion includes a first part, and a vertical projection of the first part on the plane where the substrate is located partially overlaps the vertical projection of the gate on the plane where the substrate is located.

With reference to the second aspect, in some implementations of the second aspect, the first extension portion further includes a second part, and the second part extends toward a direction from the gate to the source to a place between the gate and the source and extends toward the multilayer semiconductor layer; the vertical projection of the first part on the plane where the substrate is located and a vertical projection of the second part on the plane where the substrate is located are adjacent without overlapping.

With reference to the second aspect, in some embodiments of the second aspect, before preparing the field plate structure on the side, away from the substrate, of the multilayer semiconductor layer, the method further includes: preparing at least one dielectric layer on the side, away from the substrate, of the multilayer semiconductor layer, wherein the dielectric layer covers an upper surface and a side surface of the gate.

According to the technical solutions provided by the embodiments of the present application, the semiconductor device sequentially includes a substrate; a multilayer semiconductor layer, a source, a gate, a drain, and a field plate structure; the field plate structure includes a main body portion and a first extension portion; the main body portion is located between the gate and the drain; the first extension portion is connected to the main body portion and is located on a side, away from the multilayer semiconductor layer, of the gate; and the first extension portion at least partially overlaps the gate. By extending the field plate structure toward a side of the gate, a modulation effect of the field plate structure on an electric field may be further increased, the electric field accumulation on a side of the gate near the drain may be reduced, and the probability of the breakdown, which occurs at the side of the gate near the drain, may be reduced, thereby improving the reliability of semiconductor devices.

### BRIEF DESCRIPTION OF THE DRAWINGS

In order to more clearly illustrate the technical solutions of the exemplary embodiments of the present application, the following briefly introduces the accompanying drawings used in describing the embodiments. Obviously, the introduced accompanying drawings are only a part of the accompanying drawings to be described in this application, rather than all accompanying drawings. For those of ordinary skill in the art, other accompanying drawings may be obtained based on these accompanying drawings without paying creative work.

FIG. 1 is a schematic structural diagram of a semiconductor device according to an embodiment of the present application.

FIG. 2 is a schematic cross-sectional structure diagram of the semiconductor device provided in FIG. 1 along the section line A-A′.

FIG. 3 is a schematic structural diagram of a semiconductor device according to another embodiment of the present application.

FIG. 4 is a schematic cross-sectional structure diagram of the semiconductor device provided in FIG. 3 along the section line B-B′.

FIG. 5 is a schematic structural diagram of a semiconductor device according to another embodiment of the present application.

FIG. 6 is a schematic cross-sectional structure diagram of the semiconductor device provided in FIG. 5 along the section line B-B′.

FIG. 7 is a schematic flowchart of a preparation method of a semiconductor device according to an embodiment of the present application.

### DETAILED DESCRIPTION OF THE EMBODIMENTS

In order to make purposes, technical solutions and advantages of the present application more clearly, the following will fully describe the technical solutions of the present application through specific implementations with reference to the accompanying drawings in the embodiments of the present application. Obviously, the described embodiments are a part of the embodiments of the present application, rather than all the embodiments. Based on the embodiments of the present application, all other embodiments obtained by those of ordinary skill in the art without creative work fall within the protection scope of this application.

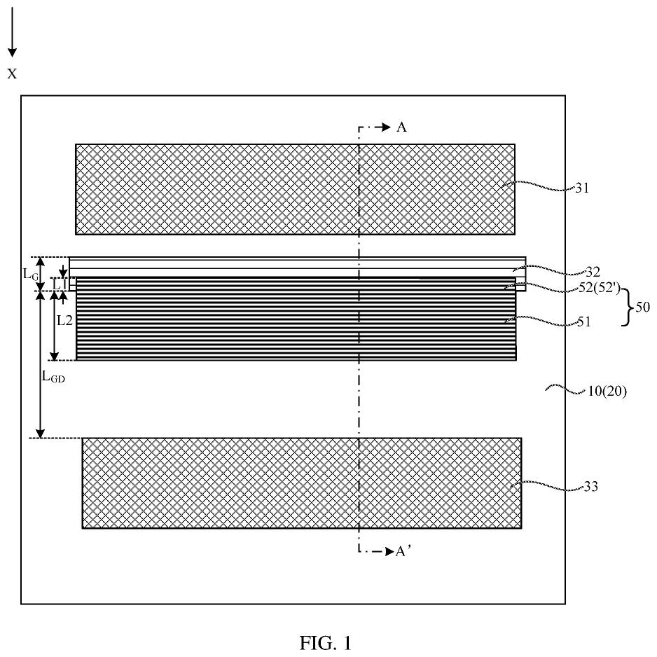

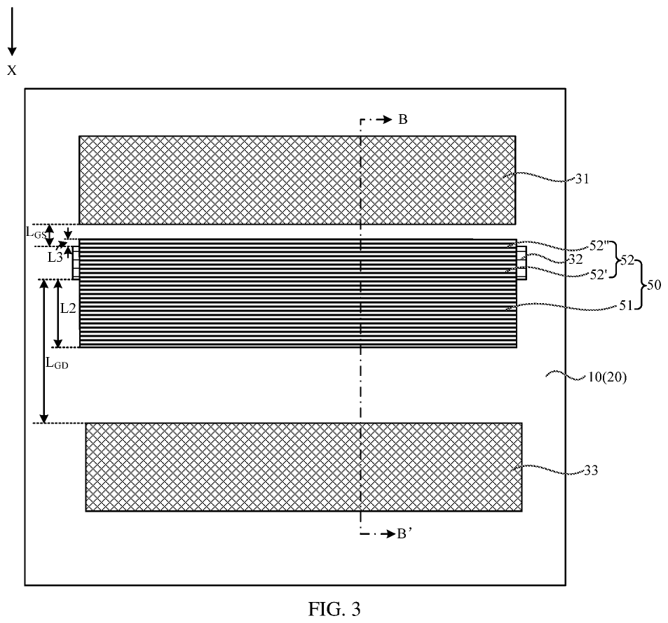

FIG. 1 is a schematic structural diagram of a semiconductor device according to an embodiment of the present application. FIG. 3 is a schematic structural diagram of a semiconductor device according to another embodiment of the present application. As shown in FIG. 1 and FIG. 3, the semiconductor device provided by the embodiments of the present application may include: a substrate 10, a multilayer semiconductor layer 20, a source 31, a gate 32, a drain 33 and a field plate structure 50.

The multilayer semiconductor layer 20 is located on a side of the substrate 10. Two-Dimensional Electron Gas (2DEG) is formed in the multilayer semiconductor layer 20.

The source 31, the gate 32 and the drain 33 are located on a side, away from the substrate 10, of the multilayer semiconductor layer 20. The gate 32 is located between the source 31 and the drain 33.

The field plate structure 50 is located on the side, away from the substrate 10, of the multilayer semiconductor layer 20. The field plate structure 50 includes a main body portion 51 and a first extension portion 52. The main body portion 51 is located between the gate 32 and the drain 33. The first extension portion 52 is connected to the main body portion 51, and the first extension portion 52 is located on a side, away from the multilayer semiconductor layer 20, of the gate 32. A vertical projection of the first extension portion 52 on a plane where the substrate 10 is located at least partially overlaps a vertical projection of the gate 32 on the plane where the substrate 10 is located.

The main body portion 51 is located between the gate 32 and the drain 33 for forming a new main body depletion region in the multilayer semiconductor layer 20 under the field plate structure 50, which increases an area of a depletion region between the gate 32 and the drain 33 and increases a source-drain voltage that the depletion region can bear, thereby increasing a breakdown voltage of the semiconductor device. In addition, by using the field plate structure 50, a part of an electric field originally concentrated on an edge of a side of the gate 32 close to the drain 33 may be collected on the field plate structure 50, so as to reduce the electric field at a position of the gate 32 close to the drain 33, thereby reducing a leakage current of the gate 32 and improving the reliability of the semiconductor device.

The first extension portion 52 is used to form a new auxiliary depletion region in the multilayer semiconductor layer 20 under the field plate structure 50, and is used to adjust a modulation effect of the main body depletion region on the electric field at a position of the gate 32 near the drain 33. Since the first extension portion 52 at least partially overlaps the gate 32, the auxiliary depletion region formed based on the first extension portion 52 can adjust the electric field toward a direction of the gate 32 away from the drain 33, so as to avoid a large amount of charges are accumulated on the side of the gate 32 close to the drain 33 and avoid breakdown which occurs at a gate corner on the side of the gate 32 close to the drain 33, thereby improving the reliability of the semiconductor device.

According to the technical solutions provided by the embodiments of the present application, the field plate structure includes a main body portion and a first extension portion; the main body portion is located between the gate and the drain; the first extension portion is connected to the main body portion, and is located at a side, away from the multilayer semiconductor layer, of the gate; and the first extension portion at least partially overlaps the gate. By extending the field plate structure toward a side of the gate, a modulation effect of the field plate structure on an electric field may be further increased, the electric field accumulation on a side of the gate near the drain may be reduced, and the probability of the breakdown, which occurs at the side of the gate near the drain, may be reduced, thereby improving the reliability of semiconductor devices.

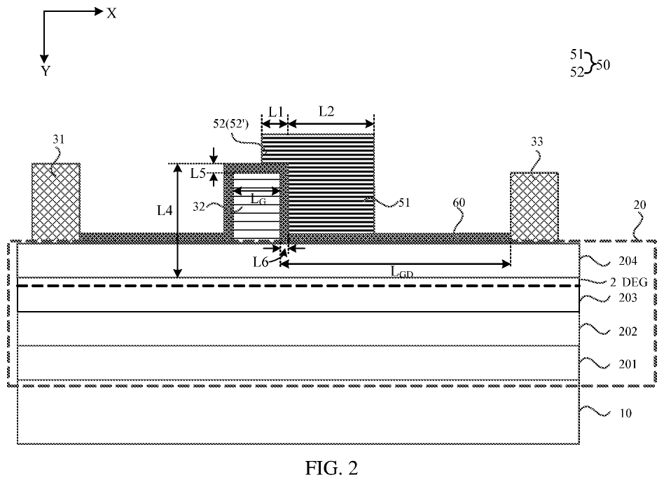

In some embodiments of the present application, in an extending direction of the gate 32 (i.e., in a gate width direction perpendicular to the X direction/in a direction perpendicular to the XY plane shown in FIG. 2), the first extension portion 52 and the main body portion 51 may have the same width, which can ensure the first extension portion 52 and the gate 32 have a larger facing area to ensure that the first extension portion 52 and the gate 32 have a larger contact area, thereby increasing the connection stability of the field plate structure 50 and further improving the working reliability of the semiconductor device.

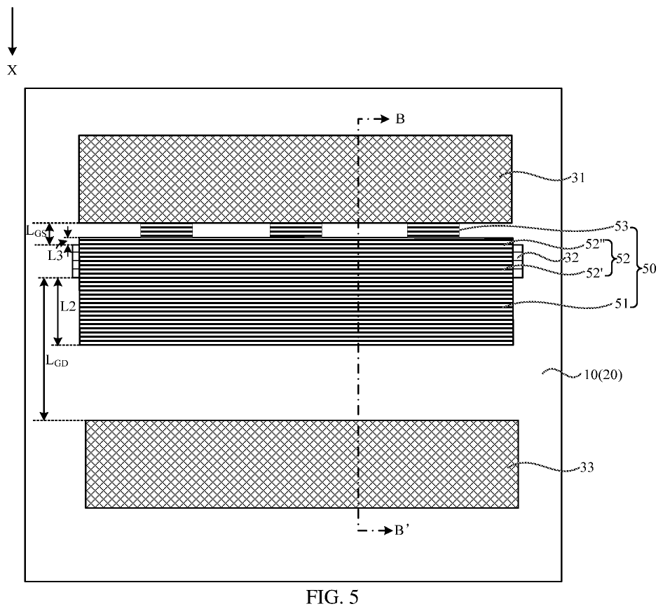

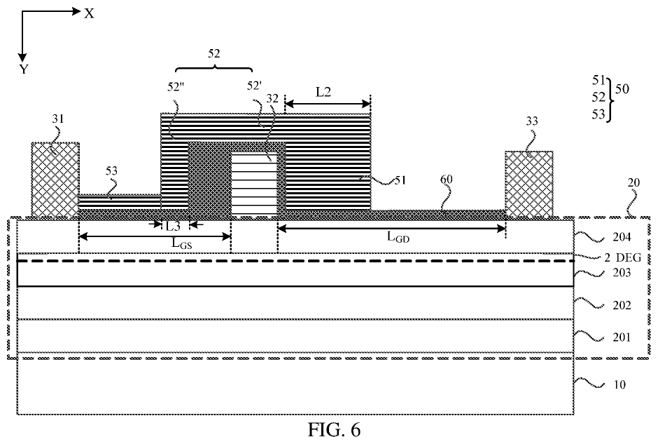

In some embodiments of the present application, the field plate structure 50 may be a metal field plate structure or a source field plate structure, which is not limited in this application. Further, the source field plate structure may further include a second extension portion 53 (as shown in FIG. 5 and FIG. 6). For example, the second extension portion 53 may be connected to or integrally formed with the first extension portion 52. The second extension portion 53 may include one or more extension branches, one or more extension branches are located between the first extension portion 52 and the source 31. One end of each extension branch is connected to the first extension portion 52, another end of each extension branch is electrically connected to the source 31, so as to realize an electrical connection between the field plate structure and the source, and realize a function of the source field plate structure; or the electrical connection between the source and the field plate structure can also be realized from the outside of the semiconductor device, thereby realizing the function of the source field plate structure, which is not limited in this application.

In some embodiments of the present application, a material of the substrate 10 may be Si, SiC or sapphire. A material of the multilayer semiconductor layer 20 may be a semiconductor material of group III-V compounds, or may be silicon or other semiconductor materials, which are not limited in this application.

In some embodiments of the present application, the source 31 and the drain 33 may form ohmic contact with the multilayer semiconductor layer 20, and the gate 32 may form Schottky contact with the multilayer semiconductor layer 20.

In some embodiments of the present application, materials of the source 31 and the drain 33 may be one or a combination of metals such as Ni, Ti, Al, and Au, and a material of the gate 32 may be one or a combination of metals such as Ni, Pt, Pb and Au, which are not limited in this application.

In some embodiments of the present application, the gate 32 may be a single-layer metal gate, or may be a double-layer metal stack or a multilayer gate structure. For example, the multilayer gate structure may be formed by disposing a MIS structure (not shown in the figure) of a layer of insulating medium (e.g., SiO₂) between the gate 32 and the multilayer semiconductor layer 20, which is not limited in this application.

In some embodiments of the present application, a cross-sectional shape of the gate 32 may be a rectangle or a T-shape, that is, a portion of the gate 32 is located in the multilayer semiconductor layer 20 to ensure that the Schottky contact between the gate 32 and the multilayer semiconductor layer 20 is good, which is not limited in this application.

In the above, the vertical projection of the first extension portion 52 on the plane where the substrate 10 is located and the vertical projection of the gate 32 on the plane where the substrate 10 is located at least partially overlap, which includes: the cases where the vertical projection of the first extension portion 52 on the plane where the substrate 10 is located and the vertical projection of the gate 32 on the plane where the substrate 10 is located partially overlap or completely overlap, which will be described in detail below.

First, the case where the vertical projection of the first extension portion 52 on the plane where the substrate 10 is located partially overlaps the vertical projection of the gate 32 on the plane where the substrate 10 is located will be described with reference to FIGS. 1 and 2.

As shown in FIGS. 1 and 2, the first extension portion 52 includes a first part 52′, and a vertical projection of the first part 52′ on the plane where the substrate 10 is located partially overlaps the vertical projection of the gate 32 on the plane where the substrate 10 is located. That is, along the X direction, the vertical projection of the first part 52′ on the plane where the substrate 10 is located covers a part of the vertical projection of the gate 32 on the plane where the substrate 10 is located; and along the direction perpendicular to the XY plane, the vertical projection of the first part 52′ on the plane where the substrate 10 is located at least covers an active area/a part of the vertical projection of the gate 32 on the plane where the substrate 10 is located. Specifically, the vertical projection of the first part 52′ on the plane where the substrate 10 is located is partially located inside the vertical projection of the gate 32 on the plane where the substrate 10 is located. A vertical projection of the main body portion 51 on the plane where the substrate 10 is located and the vertical projection of the first part 52′ on the plane where the substrate 10 is located are adjacent without overlapping.

Further, the field plate structure 50 includes the second extension portion 53, the second extension portion 53 may include one or more extension branches, one or more extension branches are located between the first part 52′ and the source 31, that is, between a surface, close to the source 31, of the gate 32 and the source 31.

Along a direction from the gate 32 to the drain 33, as shown in the X direction in the figures, the first part 52′ extends from the main body portion 51 between the gate 32 and the drain 33 to the gate 32, an extension length of the first part 52′ is L₁, and an extension length of the gate 32 is L_{G}. The extension length L₁ of the first part 52′ is not set arbitrarily, because the main body portion 51 is closer to the gate 32 than to the drain 33, the extension length of the first part 52′ is inseparable from the extension length of the gate 32, and a length relationship between them may affect the reliability and stability of the semiconductor device in working state. On the basis of ensuring the connection stability of the field plate structure, improving the reliability of the semiconductor device in the working state is an urgent problem to be solved in the structure. It has been found through research that when the extension length L₁ of the first part 52′ satisfies 0.1*L_{G}<L₁<0.65*L_{G}, the stability of the semiconductor device working under high temperature conditions may be greatly improved, thereby avoiding the rapid failure of the semiconductor device under high temperature conditions. When the extension length L₁ of the first part 52′ satisfies L₁<0.1*L_{G} or L₁>0.65*L_{G}, the stability of the semiconductor device working under high temperature conditions may be reduced to various extents, and eventually the semiconductor device may even fail under high temperature conditions. Therefore, by controlling a proportional relationship between the extension length of the first part of the first extension portion and the extension length of the gate itself, the effective reliability of the semiconductor device in a high temperature environment may be improved, and the application range of the semiconductor device may be greatly expanded.

In addition, in the research process, it was found that when the extension length of the first part 52′ is set to improve the stability of the semiconductor device working under high temperature conditions, a relationship between an extension length of the main body portion 51 and the extension length of the first part 52′ also affects the stability of the semiconductor device working under high temperature conditions, and further affects working performances of the semiconductor device. As shown in FIG. 1, along the direction from the gate 32 to the drain 33, the extension length of the main body portion 51 is L₂. When L₂>L₁, the stability of the semiconductor device at high temperature conditions can be further optimized. Preferably, when L₂≥1.5*L₁, the stability of the semiconductor device at high temperature conditions is better.

By setting the extension length L₁ of the first part 52′ of the first extension portion 52 and the extension length L_{G} of the gate 32 to satisfy 0.1*L_{G}<L₁<0.65*L_{G}, on the one hand, it can be ensured that the first extension portion 52 may not only adjust the electric field at a position of the gate 32 near the drain 33 and achieve an optimal contact area with the gate, and may increase the stability of the semiconductor device working under high temperature conditions; on the other hand, it can also be ensured that a coupling capacitance between the first extension portion 52 and the gate 32 is small, and effect on power characteristics and frequency characteristics of the semiconductor device are small, thereby greatly improving the working performances of the semiconductor device.

In some embodiments of the present application, the extension length L_{G} of the gate 32 may satisfy 400 nm<L_{G}<2000 nm, and preferably, the extension length L_{G} of the gate metal 32 satisfies 400 nm<L_{G}<1300 nm. By reasonably setting the extension length of the gate 32, the semiconductor device can be ensured to have a suitable size and the semiconductor device can work normally. Further, the extension length of the first part 52′ of the first extension portion 52 satisfies 0.1*L_{G}<L₁<0.65*L_{G}, this structure can ensure that the coupling capacitance between the first extension portion 52 and the gate 32 is small, which has little effect on the power characteristics and frequency characteristics of the semiconductor device. Furthermore, as the extension length of the main body portion 51 satisfies L₂>L₁, the working stability of the semiconductor device under high temperature conditions may be further improved, performances of the semiconductor device is greatly improved, and the adaptability of the semiconductor device to high temperature environment is especially improved.

It should be noted that, the embodiments of the present application only take the example that the extension length L_{G} of the gate 32 satisfies 400 nm<L_{G}<2000 nm for description, rather than limiting the embodiments of the present application. Under the condition that the vertical projection of the first extension portion 52 on the plane where the substrate 10 is located and the vertical projection of the gate 32 on the plane where the substrate 10 is located partially overlap, the extension length L₁ of the first part 52′ of the first extension portion 52 may vary with the extension length L_{G} of the gate 32, which also falls within the protection scope of the embodiments of the present application.

According to the technical solutions provided by the embodiments of the present application, by setting the vertical projection of the first extension portion 52 on the plane where the substrate 10 is located to partially overlap the vertical projection of the gate 32 on the plane where the substrate 10 is located, on the one hand, it can be ensured that the auxiliary depletion region formed by the first extension portion 52 can adjust the electric field toward the direction of the gate 32 away from the drain 33, so as to avoid a large amount of charges are accumulated on the side of the gate 32 close to the drain 33 and avoid breakdown which occurs at a gate corner on the side of the gate 32 close to the drain 33. By setting the first extension portion 52 and the main body portion 51 to have the same width in the extension direction of the gate 32 (that is, in the gate width direction perpendicular to the X direction), it is possible to increase the facing area between the first extension portion 52 and the gate 32, which ensures that the first extension portion 52 and the gate 32 have a larger contact area, thereby increasing the connection stability of the field plate structure 50 and further increasing the reliability of the semiconductor device. By setting the extension length of the first part 52′ of the first extension portion 52 to satisfy 0.1*L_{G}<L₁<0.65*L_{G}, it can ensure that the coupling capacitance formed between the first extension portion 52 and the gate 32 is small, reducing the effect of the coupling capacitance on the power characteristics and frequency characteristics of semiconductor devices and ensuring that the semiconductor devices have good power characteristics and frequency characteristics.

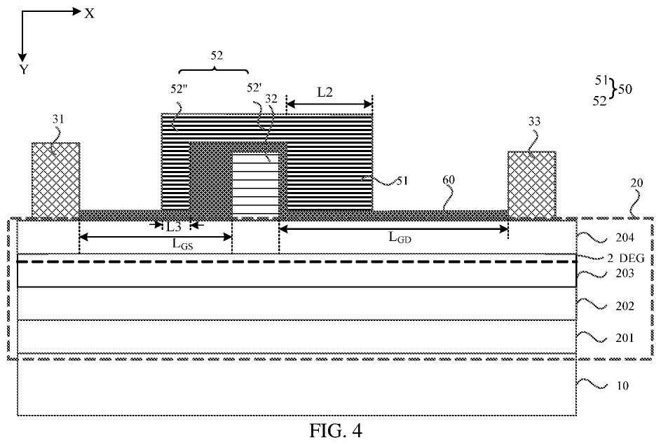

Next, the case where the vertical projection of the first extension portion 52 on the plane where the substrate 10 is located completely overlaps the vertical projection of the gate 32 on the plane where the substrate 10 is located will be described with reference to FIGS. 3 and 4.

As shown in FIG. 3 and FIG. 4, the first extension portion 52 includes a first part 52′ and a second part 52″. The vertical projection of the first part 52′ on the plane where the substrate 10 is located partially overlaps the vertical projection of the gate 32 on the plane where the substrate 10 is located. The second part 52″ extends toward a direction from the gate 32 to the source 31 to a place between the gate 32 and the source 31, and extends toward the multilayer semiconductor layer 20. The second part 52″ is located between the source 31 and the gate 32. The vertical projection of the first part 52′ on the plane where the substrate 10 is located and a vertical projection of the second part 52″ on the plane where the substrate 10 is located are adjacent without overlapping. That is, between the source 31 and the drain 33, the field plate main body portion 51 and the first extension portion 52 form a surrounding cavity for the gate 32. Along the X direction, the vertical projection of the first part 52′ on the plane where the substrate 10 is located covers the vertical projection of the gate 32 on the plane where the substrate 10 is located; and along the direction perpendicular to the XY plane, the vertical projection of the first part 52′ on the plane where the substrate 10 is located at least covers an active area/a part of the vertical projection of the gate 32 on the plane where the substrate 10 is located.

Further, the field plate structure 50 includes the second extension portion 53, the second extension portion 53 may include one or more extension branches, one or more extension branches are located between the second part 52″ and the source 31, that is, between the gate 32 and the source 31.

The main body portion 51 and the first extension portion 52 of the field plate structure form a surrounding cavity for the gate 32. On the one hand, it can be ensured that the auxiliary depletion region formed based on the first extension portion 52 has a strong modulation effect on the electric field that forms at a side of the gate 32 close to the drain 33, and the electric field can be adjusted to a larger distance toward the side of the gate 32 away from the drain 33, so that the accumulation of a large amount of charges on the side of the gate 32 close to the drain 33 may be completely avoided, and the breakdown which occurs at a gate corner on the side of the gate 32 close to the drain 33 may be avoided, which improves the reliability of the semiconductor device. On the other hand, the frequency characteristic of the semiconductor device may be greatly improved to meet the increasing frequency characteristics faced by the semiconductor device.

In some embodiments of the present application, when other film layers exist on the surface of the multilayer semiconductor layer 20, such as a dielectric layer 60 shown in FIG. 4, the second part 52″ extends to the surface of the dielectric layer 60 toward the direction of the multilayer semiconductor layer 20. Preferably, between the source 31 and the drain 32, a contact surface between a bottom of the second part 52″ and the dielectric layer 60 is located between the upper and lower surfaces of the gate 32.

In some embodiments of the present application, as shown in FIGS. 3 and 4, along a direction from the source 31 to the drain 33, as shown in the X direction in the figures, an extension length of the second part 52″ between the gate 32 and the source 31 is L₃, and a distance between the gate 32 and the source 31 is L_{GS}, where 0<L₃<0.5*L_{GS}.

By setting the extension length L₃ of the second part 52″ of the first extension portion 52 between the gate 32 and the source 31 and the distance L_{GS} between the gate 32 and the source 31 to satisfy 0<L₃<0.5*L_{GS}, and L₃<L₂, it can not only ensure that the first extension portion 52 has a strong adjustment effect on the electric field, but also improve the frequency characteristics of the device and increase the reliability of the semiconductor device; and it can also ensure that the facing area between the first extension portion 52 and the gate 32 is larger, the connection stability of the field plate structure 50 is increased, and a gate-source capacitance is reduced as much as possible, thereby further increasing the working reliability of the semiconductor device.

Preferably, the extension length L₃ of the second part 52″ between the gate 32 and the source 31 and the distance L_{GS} between the gate 32 and the source 31 satisfy 0.01*L_{GS}<L₃<0.3*L_{GS} and L₃<L₂. It should be understood that the above description is only a preferred solution. Under the condition that the vertical projection of the first extension portion 52 on the plane where the substrate 10 is located and the vertical projection of the gate 32 on the plane where the substrate 10 is located completely overlap, other correspondences between the extension length L₃ of the second part 52″ between the gate 32 and the source 31 and the distance L_{GS} between the gate 32 and the source 31 also fall in the protection scope of the embodiment of the present application, which is not limited in the present application.

Alternatively, the first extension portion 52 includes a first part 52′, along the X direction, the vertical projection of the first part 52′ on the plane where the substrate 10 is located covers the vertical projection of the gate 32 on the plane where the substrate 10 is located; and along the direction perpendicular to the XY plane, the vertical projection of the first part 52′ on the plane where the substrate 10 is located at least covers an active area/a part of the vertical projection of the gate 32 on the plane where the substrate 10 is located.

In some embodiments of the present application, the semiconductor device may further include at least one dielectric layer 60. As shown in FIG. 2, FIG. 2 only takes one dielectric layer 60 as an example for illustration. The dielectric layer 60 covers an upper surface and a side surface of the gate 32, along a direction perpendicular to the substrate 10, a thickness L₅ of the dielectric layer 60 on the upper surface of the gate 32 may satisfy 50 nm<L₅<300 nm; and along the direction from the gate 32 to the drain 33, an extension length L₆ of the dielectric layer 60 on the side surface of the gate 32 may satisfy 50 nm<L₆<300 nm, and L₆=L₅.

The gate 32 can be protected by covering the upper surface and the side surface of the gate 32 with the dielectric layer 60. In addition, by reasonably setting the thickness L₅ of the dielectric layer 60 to satisfy 50 nm<L₅<300 nm, and setting the extension length L₆ of the dielectric layer 60 to satisfy 50 nm<L₆<300 nm, along the direction from the gate 32 to the drain 33, on the one hand, the breakdown of the dielectric layer 60 may be avoided; on the other hand, the coupling capacitance between the gate 32 and the source 31 may be reduced as much as possible, and the effect of the coupling capacitance on the power characteristics and frequency characteristics of the semiconductor device can be reduced, so as to ensure that the semiconductor device has good power characteristics and frequency characteristics.

In some embodiments of the present application, with continued reference to FIGS. 1-6, along the direction from the gate 32 to the drain 33, the extension length of the main body portion 51 is L₂, and a distance between the gate 32 and the drain 33 is L_{GD}, where L₂<0.6*L_{GD}.

The extension length L₂ of the main body portion 51 and the distance L_{GD} between the gate 32 and the drain 33 satisfy L₂<0.6*L_{GD}, a contact surface between a bottom of the main body portion 51 and the dielectric layer 60 is located between the upper and lower surfaces of the gate 32, and thus the electric field distribution near the gate of the semiconductor device may be preferentially improved. In addition, a distance between the main body portion 51 and the drain 33 is relatively large, which may ensure that the capacitance between the drain 33 and the source 31 is small, and avoid power characteristics and frequency characteristics of semiconductor devices being affected by the coupling capacitance.

In some embodiments of the present application, with continued reference to FIG. 2, FIG. 4 and FIG. 6, the multilayer semiconductor layer 20 may include: a nucleation layer 201 located on the substrate 10; a buffer layer 202 located on a side of the nucleation layer 201 away from the substrate 10; a channel layer 203 located on a side of the buffer layer 202 away from the nucleation layer 201; and a barrier layer 204 located on a side of the channel layer 203 away from the buffer layer 202.

In some embodiments of the present application, as shown in FIG. 2, along the direction perpendicular to the substrate 10, such as the Y direction shown in the figure, a distance L₄ between the first extension portion 52 and the channel layer 203 may satisfy 300 nm<L₄<2000 nm.

By reasonably setting the distance L₄ between the first extension portion 52 and the channel layer 203 to satisfy 300 nm<L₄<2000 nm, it can ensure that the first extension portion 52 has a good adjustment effect on the electric field that forms at a side of the gate 32 close to the drain 33, that is, the electric field is adjusted toward the direction of the gate 32 away from the drain 33 to avoid accumulating a large amount of charges on the side of the gate 32 close to the drain 33, and to avoid breakdown which occurs at a gate corner on the side of the gate 32 close to the drain 33, thereby improving the reliability of the semiconductor device.

In some embodiments of the present application, materials of the nucleation layer 201 and the buffer layer 202 may be nitrides, specifically GaN or aluminum nitride (AlN) or other nitrides, or silicon or other semiconductor materials. The nucleation layer 201 and the buffer layer 202 may be used to match the material of substrate 10 and an epitaxial channel layer 203. A material of the channel layer 203 may be GaN or Indium Aluminum Nitride (InAlN), and may also be silicon or other semiconductor materials. The barrier layer 204 is located above the channel layer 203, and a material of the barrier layer 204 may include a gallium compound semiconductor material or a nitride semiconductor material, such as InₓAl_{y}Ga_{z}N_{1-x-y-z}, where 0≤x≤1, 0≤y≤1, 0≤z≤1. Optionally, the channel layer 203 and the barrier layer 204 form a semiconductor heterojunction structure, and a high-concentration two-dimensional electron gas is formed at an interface of the channel layer 203 and the barrier layer 204. Optionally, a material of the barrier layer 204 can also be silicon or other semiconductor materials. Therefore, the multilayer semiconductor layer 20 provided in the embodiments of the present application may be a semiconductor material of a III-V group compound, or may be silicon or other semiconductor materials, which is not limited in the present application.

It should be understood that the embodiments of the present application improve the reliability of the semiconductor device from a perspective of structure design of the semiconductor device. The above-mentioned semiconductor devices include but are not limited to: high-power gallium nitride High Electron Mobility Transistor (HEMT) working in a high-voltage and high-current environment, Silicon-On-Insulator (SOI) structure transistors, gallium arsenide (GaAs)-based transistor, and Metal-Oxide-Semiconductor Field-Effect Transistor (MOSFET), Metal-Insulator-Semiconductor Field-Effect Transistor (MISFET), Double Heterojunction Field-Effect Transistor (DHFET), Junction Field-Effect Transistor (JFET), Metal-Semiconductor Field-Effect Transistor (MESFET), Metal-Insulator-Semiconductor Heterojunction Field-Effect Transistor (MISHFET) or other field effect transistors.

All the above-mentioned optional technical solutions can be combined arbitrarily to form optional embodiments of the present application, which will not be repeated here.

Based on the same inventive concept, the embodiments of the present application also provide a preparation method of a semiconductor device. For details not disclosed in the method embodiments of the present application, please refer to the above device embodiments.

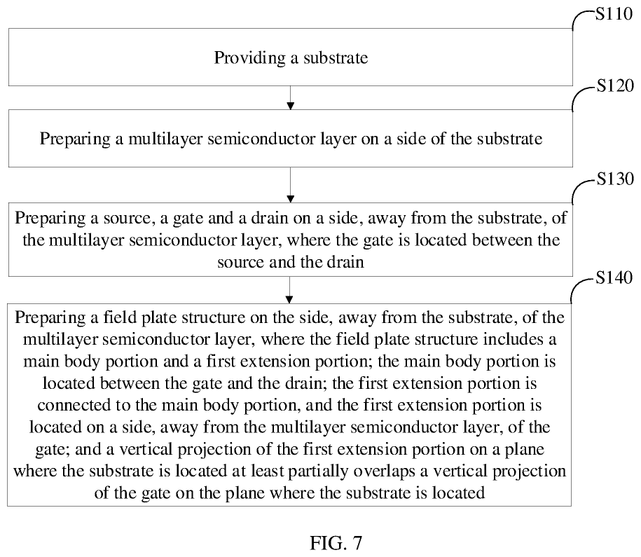

As shown in FIG. 7, the preparation method of a semiconductor device provided by the embodiment of the present application may include step S110, step S120, step S130 and step S140.

S110, providing a substrate.

The material of the substrate may be Si, SiC or sapphire, and may also be other materials suitable for growing semiconductor materials, which are not limited in this application.

A preparation method of the substrate may be atmospheric pressure chemical vapor deposition method, sub-atmospheric pressure chemical vapor deposition method, metal organic compound vapor deposition method, low pressure chemical vapor deposition method, high density plasma chemical vapor deposition method, ultra-high vacuum chemical vapor deposition method, plasma enhanced chemical vapor deposition method, catalytic chemical vapor deposition method, hybrid physical-chemical vapor deposition method, rapid thermal chemical vapor deposition method, vapor phase epitaxy method, pulsed laser deposition method, atomic layer epitaxy method, molecular beam epitaxy method or sputtering method or evaporation method, which is not limited in this application.

S120, preparing a multilayer semiconductor layer on a side of the substrate.

A two-dimensional electron gas is formed in the multilayer semiconductor layer. The material of the multilayer semiconductor layer may be a semiconductor material of III-V compounds, or may be silicon or other semiconductor materials, which is not limited in this application.

S130, preparing a source, a gate and a drain on a side, away from the substrate, of the multilayer semiconductor layer, where the gate is located between the source and the drain.

For example, the source and the drain may form ohmic contact with the multilayer semiconductor layer, and the gate may form Schottky contact with the multilayer semiconductor layer.

The materials of source and drain may be one or a combination of Ni, Ti, Al, Au and other metals, and the material of the gate may be one or a combination of Ni, Pt, Pb, Au and other metals, which are not limited in this application.

The gate may be a single-layer metal gate, or a double-layer metal stack or a multilayer gate structure, which is not limited in this application.

The shape of the gate may be rectangular or T-shaped, which is not limited in this application.

S140, preparing a field plate structure on the side, away from the substrate, of the multilayer semiconductor layer, where the field plate structure includes a main body portion and a first extension portion; the main body portion is located between the gate and the drain; the first extension portion is connected to the main body portion, and the first extension portion is located on a side, away from the multilayer semiconductor layer, of the gate; and a vertical projection of the first extension portion on a plane where the substrate is located at least partially overlaps a vertical projection of the gate on the plane where the substrate is located.

The main body portion forms a new main body depletion region in the multilayer semiconductor layer under the field plate structure near the gate, which may increase an area of a depletion region between the gate and the drain, and improve a source-drain voltage that the depletion region can bear. Thus, a breakdown voltage of the semiconductor device is increased.

The first extension portion forms a new auxiliary depletion region in the multilayer semiconductor layer under the field plate structure for adjusting a modulation effect of the main body depletion region on the electric field. Since the first extension portion at least partially overlaps the gate, the auxiliary depletion region formed by the first extension may adjust the electric field toward a direction of the gate away from the drain, so as to avoid accumulating a large amount of charges on a side of the gate close to the drain, and avoid breakdown which occurs at a gate corner on the side of the gate close to the drain, thereby improving the reliability of the semiconductor device.

According to the technical solutions provided by the embodiments of the present application, the field plate structure includes a main body portion and a first extension portion, the main body portion is located between the gate and the drain; the first extension portion is connected to the main body portion, and is located at a side, away from the multilayer semiconductor layer, of the gate; and the first extension portion at least partially overlaps the gate. By extending the field plate structure toward a side of the gate, on the one hand, a modulation effect of the field plate structure on an electric field may be further increased, the electric field accumulation on a side of the gate near the drain may be reduced, and the probability of the breakdown, which occurs at the side of the gate near the drain, may be reduced, thereby improving the reliability of semiconductor devices.

In some embodiments of the present application, the first extension portion includes a first part, a vertical projection of the first part on the plane where the substrate is located partially overlaps the vertical projection of the gate on the plane where the substrate is located.

In some embodiments of the present application, along a direction from the gate to the drain, an extension length of the first part is L₁, and an extension length of the gate is L_{G}, where 0.1*L_{G}<L₁<0.65*L_{G}. By controlling a proportional relationship between the extension length of the first part and the extension length of the gate itself, the effective reliability of the semiconductor device in a high temperature environment may be improved, the rapid failure of the semiconductor device in a high temperature state may be avoided, and the application range of the semiconductor device may be greatly expanded.

In some embodiments of the present application, along a direction from the gate to the drain, an extension length of the first part is L₁, and an extension length of the main body portion is L₂, where L₁<L₂.

In some embodiments of the present application, the first extension portion further includes a second part, the second part extends toward a direction from the gate to the source to a place between the gate and the source and extends toward the multilayer semiconductor layer. The vertical projection of the first part on the plane where the substrate is located and a vertical projection of the second part on the plane where the substrate is located are adjacent without overlapping. That is to say, the main body portion of the field plate and the first extension portion form a surrounding cavity for the gate, and in this way, the frequency characteristic of the semiconductor device may be greatly improved to meet the increasing frequency characteristic faced by the semiconductor device.

In some embodiments of the present application, along a direction from the gate to the drain, an extension length of the second part between the gate and the source is L₃, and a distance between the gate and the source is L_{GS}, where 0<L₃<0.5*L_{GS}.

In some embodiments of the present application, along a direction from the gate to the drain, an extension length of the main body portion is L₂, and a distance between the gate and the drain is L_{GD}, where L₂<0.6*L_{GD}.

In some embodiments of the present application, the multilayer semiconductor layer includes a nucleation layer, a buffer layer, a channel layer and a barrier layer arranged in sequence, and a two-dimensional electron gas is formed in the multilayer semiconductor layer.

In some embodiments of the present application, along a direction perpendicular to the substrate, a distance L₄ between the first extension portion and the channel layer satisfies 300 nm<L₄<2000 nm.

In some embodiments of the present application, in an extension direction of the gate, a width of the first extension portion and a width of the main body portion are the same, which can increase the facing area between the field plate structure and the gate, and increase the stability of the field plate structure, thereby further improving the reliability of semiconductor devices.

In some embodiments of the present application, before step S140, the above-mentioned preparation method of a semiconductor device may further include: preparing at least one dielectric layer on the side, away from the substrate, of the multilayer semiconductor layer, where the dielectric layer covers an upper surface and a side surface of the gate.

In some embodiments, along the direction perpendicular to the substrate, a thickness L₅ of the dielectric layer may satisfy 50 nm<L₅<300 nm; and along the direction from the gate to the drain, an extension length L₆ of the dielectric layer may satisfy 50 nm<L₆<300 nm.

The gate can be protected by covering the upper surface and the side surface of the gate with a dielectric layer. In addition, by reasonably setting the thickness L₅ of the dielectric layer to satisfy 50 nm<L₅<300 nm, and setting the extension length L₆ of the dielectric layer satisfy 50 nm<L₆<300 nm, along the direction from the gate to the drain, on the one hand, the breakdown of the dielectric layer may be avoided; on the other hand, the coupling capacitance between the gate and the source may be reduced as much as possible, and the effect of the coupling capacitance on the power characteristics and frequency characteristics of the semiconductor device can be reduced, thereby ensuring that the semiconductor device has good power characteristics and frequency characteristics.

In addition, it should also be noted that the combination of the technical features in this case is not limited to the combination described in the claims of this case or the combination described in the specific embodiments, and all the technical features described in this case can be freely combined in any way, unless there is a conflict with each other.

It should be noted that the above examples only specific embodiments of the present application. Obviously, the present application is not limited to the above embodiments, and there are many similar changes. All modifications directly derived or associated by those skilled in the art from the content disclosed in this application, shall fall within the protection scope of this application.

It should be understood that the qualifiers such as first and second mentioned in the embodiments of the present application are only used to describe the technical solutions of the embodiments of the present application more clearly, and cannot be used to limit the protection scope of the present application.

The above are only preferred embodiments of the present application, and are not intended to limit the protection scope of the present application. Any modification, equivalent replacement, improvement, etc. made within the spirit and principle of this application shall be included within the protection scope of this application.

What is claimed is:

1. A semiconductor device, comprising:
a substrate;
a multilayer semiconductor layer located on a side of the substrate;
a source, a gate and a drain located on a side, away from the substrate, of the multilayer semiconductor layer, wherein the gate is located between the source and the drain; and
a field plate structure located on the side, away from the substrate, of the multilayer semiconductor layer, wherein the field plate structure comprises a main body portion and a first extension portion; the main body portion is located between the gate and the drain; the first extension portion is connected to the main body portion, and the first extension portion is located on a side, away from the multilayer semiconductor layer, of the gate; and a vertical projection of the first extension portion on a plane where the substrate is located at least partially overlaps a vertical projection of the gate on the plane where the substrate is located.

2. The semiconductor device according to claim 1, wherein the first extension portion comprises a first part, and a vertical projection of the first part on the plane where the substrate is located partially overlaps the vertical projection of the gate on the plane where the substrate is located.

3. The semiconductor device according to claim 2, wherein along a direction from the gate to the drain, an extension length of the first part is L₁, and an extension length of the gate is L_{G}, wherein 0.1*L_{G}<L₁<0.65*L_{G}.

4. The semiconductor device according to claim 3, wherein 400 nm<L_{G}<2000 nm.

5. The semiconductor device according to claim 3, wherein along the direction from the gate to the drain, an extension length of the main body portion is L₂, wherein L₁<L₂.

6. The semiconductor device according to claim 2, wherein along a direction from the gate to the drain, an extension length of the first part is L₁, and an extension length of the main body portion is L₂, wherein L₁<L₂.

7. The semiconductor device according to claim 2, wherein the first extension portion further comprises a second part, and the second part extends toward a direction from the gate to the source to a place between the gate and the source and extends toward the multilayer semiconductor layer; and the vertical projection of the first part on the plane where the substrate is located and a vertical projection of the second part on the plane where the substrate is located are adjacent without overlapping.

8. The semiconductor device according to claim 7, wherein along a direction from the gate to the drain, an extension length of the second part between the gate and the source is L₃, and a distance between the gate and the source is L_{GS}, wherein 0<L₃<0.5*L_{GS}.

9. The semiconductor device according to claim 8, wherein along the direction from the gate to the drain, an extension length of the main body portion is L₂, wherein L₃<L₂.

10. The semiconductor device according to claim 1, wherein along a direction from the gate to the drain, an extension length of the main body portion is L₂, and a distance between the gate and the drain is L_{GD}, wherein L₂<0.6*L_{GD}.

11. The semiconductor device according to claim 1, wherein the multilayer semiconductor layer comprises a nucleation layer, a buffer layer, a channel layer and a barrier layer arranged in sequence, and a two-dimensional electron gas is formed in the multilayer semiconductor layer.

12. The semiconductor device according to claim 11, wherein along a direction perpendicular to the substrate, a distance L₄ between the first extension portion and the channel layer satisfies 300 nm<L₄<2000 nm.

13. The semiconductor device according to claim 1, wherein the semiconductor device further comprises at least one dielectric layer, and the dielectric layer covers an upper surface and a side surface of the gate.

14. The semiconductor device according to claim 13, wherein along a direction perpendicular to the substrate, a thickness L₅ of the dielectric layer on the upper surface of the gate satisfies 50 nm<L₅<300 nm; and along a direction from the gate to the drain, an extension length L₆ of the dielectric layer on the side surface of the gate satisfies 50 nm<L₆<300 nm.

15. The semiconductor device according to claim 1, wherein in an extending direction of the gate, a width of the first extension portion and a width of the main body portion are the same.

16. The semiconductor device according to claim 1, wherein the field plate structure further comprises a second extension portion, the second extension portion comprises one or more extension branches located between the gate and the source, one end of each extension branch is connected to the first extension portion, another end of each extension branch is electrically connected to the source.

17. A preparation method of a semiconductor device, comprising:
providing a substrate;
preparing a multilayer semiconductor layer on a side of the substrate;
preparing a source, a gate and a drain on a side, away from the substrate, of the multilayer semiconductor layer, wherein the gate is located between the source and the drain; and
preparing a field plate structure on the side, away from the substrate, of the multilayer semiconductor layer, wherein the field plate structure comprises a main body portion and a first extension portion; the main body portion is located between the gate and the drain; the first extension portion is connected to the main body portion, and the first extension portion is located on a side, away from the multilayer semiconductor layer, of the gate; and a vertical projection of the first extension portion on a plane where the substrate is located at least partially overlaps a vertical projection of the gate on the plane where the substrate is located.

18. The preparation method of a semiconductor device according to claim 17, wherein the first extension portion comprises a first part, and a vertical projection of the first part on the plane where the substrate is located partially overlaps the vertical projection of the gate on the plane where the substrate is located.

19. The preparation method of a semiconductor device according to claim 18, wherein the first extension portion further comprises a second part, and the second part extends toward a direction from the gate to the source to a place between the gate and the source and extends toward the multilayer semiconductor layer; and the vertical projection of the first part on the plane where the substrate is located and a vertical projection of the second part on the plane where the substrate is located are adjacent without overlapping.

20. The preparation method of a semiconductor device according to claim 17, wherein before preparing the field plate structure on the side, away from the substrate, of the multilayer semiconductor layer, the method further comprises:
preparing at least one dielectric layer on the side, away from the substrate, of the multilayer semiconductor layer, wherein the dielectric layer covers an upper surface and a side surface of the gate.
